(19) United States
(12) Patent Application Publication
(10) Pub. No.: US 2024/0365670 A1
(43) Pub. Date: Oct. 31, 2024

(54) PIEZOELECTRIC ACTUATING APPARATUS

(71) Applicant: Coretronic MEMS Corporation, MIAOLI COUNTY (TW)

(72) Inventors: Hao-Chien Cheng, Miaoli County (TW); Kai-Chih Liang, Miaoli County (TW); Ming-Ching Wu, Miaoli County (TW)

(73) Assignee: Coretronic MEMS Corporation, MIAOLI COUNTY (TW)

(21) Appl. No.: 18/641,417

(22) Filed: Apr. 21, 2024

(30) Foreign Application Priority Data
Apr. 25, 2023 (CN) 202310450925.5

(51) Int. Cl. H10N 30/20; B81B 3/00; G02B 26/08; H10N 30/80

(52) U.S. Cl. CPC H10N 30/206; B81B 3/0021; H10N 30/802; B81B 2203/0163; B81B 2203/0346; B81B 2203/04; B81B 2203/058; G02B 26/0858

(57) ABSTRACT

A piezoelectric actuating apparatus includes a frame having an opening, a rotatable element, first and second actuating elements, a sensing element, transmission elements, a sensing electrode, and a driving electrode. The rotatable element is in the opening, connected to the frame via a rotating shaft structure, and reciprocatingly swings relative to the frame around an axis of the rotating shaft structure as a center. The first actuating element is connected to the rotatable element. The transmission elements are between the first and second actuating elements, and between the first actuating element and the sensing element. The second actuating element and the sensing element are coupled to the rotatable element via the transmission elements. The sensing electrode is on a part of the transmission elements and the sensing element. The driving electrode is on another part of the transmission elements and the first and second actuating elements.

### CROSS-REFERENCE TO RELATED APPLICATION

This application claims the priority benefit of China application serial no. 202310450925.5 filed on Apr. 25, 2023. The entirety of the above-mentioned patent application is hereby incorporated by reference herein and made a part of this specification.

### BACKGROUND OF THE INVENTION

### Field of the Invention

The invention relates to an actuating apparatus, and in particular to a piezoelectric actuating apparatus.

### Description of Related Art

Reflective micromirrors may be used in optical projection, optical communication, and optical ranging radar applications, etc. Compared with micromirrors manufactured by precision machining and micromirror elements designed by micro electro-mechanical systems (hereinafter referred to as MEMS) combined with semiconductor process integrated manufacturing techniques, reflective micromirrors may achieve advantages such as mass production, cost saving, miniaturization, and integration of electronic circuits. The driving methods of micromirrors may be mainly divided into three types, namely electrostatic driving, electromagnetic driving, and piezoelectric driving.

The electrostatic driving method adopts a plurality of sets of parallel interleaved capacitor plates to drive the micromirrors by means of the electrostatic force generated by the fringe effect caused by the electric field at the parallel capacitor plates. However, the distance between the comb actuators used in electrostatically driven micromirrors should not be too far from each other due to the consideration of electrostatic force, thus increasing the risk of electrode short circuit and process difficulty.

The electromagnetic driving method involves laying electromagnetic coils on the micromirrors and disposing magnetic materials outside the micromirrors. However, dense coils and high current result in poor heat dissipation and power consumption issues, thus affecting the reliability of elements. The magnetic material providing the magnetic field is difficult to be integrated in the semiconductor manufacturing process, and the magnetic material and the micromirrors need to be integrated by assembly, thus significantly increasing the volume of the system.

The piezoelectric driving method is based on the characteristics of the piezoelectric material. When an external voltage is applied to the piezoelectric material, the piezoelectric material generates a strain force, so as to drive the rotation of the micromirrors via the strain force of the piezoelectric material. The current actuators for piezoelectrically driven micromirrors are mostly designed with a folding cantilever beam design (folding beam) to superimpose the amount of deformation of the actuator. However, the design of the folded beam occupies a large area, and there is also the issue of insufficient rigidity of the micromirrors.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the invention was acknowledged by a person of ordinary skill in the art.

### SUMMARY OF THE INVENTION

The invention provides a piezoelectric actuating apparatus that may achieve the effects of high control accuracy, large scanning angle, and high scanning frequency under the design of small element size.

Other objects and advantages of the invention may be further understood from the technical features disclosed in the invention.

In order to achieve one or part or all of the above objects or other objects, an embodiment of the invention provides a piezoelectric actuating apparatus including a frame, a rotatable element, a first actuating element, a second actuating element, a sensing element, a plurality of transmission elements, a sensing electrode, and a driving electrode. The frame has an opening. The rotatable element is located in the opening and connected to the frame via a rotating shaft structure. The rotating shaft structure has an axis. The rotatable element is configured to reciprocatingly swing relative to the frame around the axis as a center. The first actuating element is disposed between the frame and the rotatable element, and the first actuating element is connected to the rotatable element. The second actuating element is disposed between the frame and the rotatable element, and the second actuating element is connected to the frame. The sensing element is disposed between the frame and the rotatable element, and the sensing element is connected to the frame. The sensing element and the second actuating element are symmetrically disposed at two opposite sides of the axis of the rotating shaft structure with the axis as the center. The transmission elements are disposed between the first actuating element and the second actuating element and between the first actuating element and the sensing element, and the second actuating element and the sensing element are coupled to the rotatable element via the transmission elements. The sensing electrode is disposed on a part of the transmission elements and the sensing element. The driving electrode is disposed on another part of the transmission elements, the first actuating element, and the second actuating element.

Based on the above, in the piezoelectric actuating apparatus of an embodiment of the invention, the second actuating element and the sensing element are coupled to the rotatable element via the transmission elements, and the piezoelectric actuating apparatus is designed such that the first actuating element, the second actuating element, the transmission elements, and the sensing element are symmetrically disposed in the frame with the rotatable element as the center. Therefore, the piezoelectric actuating apparatus may achieve the effects of high control accuracy, large scanning angle, and high scanning frequency under the design of small element size. Moreover, since the piezoelectric material is used as the material of the actuating elements, the piezoelectric actuating apparatus also readily meets the requirement of easy mass production.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic top view of a piezoelectric actuating apparatus according to an embodiment of the invention.

FIG. 2 is a schematic perspective view of a piezoelectric actuating apparatus according to an embodiment of the invention.

FIG. 3 is a schematic cross-sectional view along section line A-A′ in FIG. 1 or FIG. 2.

FIG. 4 is a schematic cross-sectional view along section line B-B′ in FIG. 1 or FIG. 2.

FIG. 5 is an enlarged perspective view of a region R1 in FIG. 1.

FIG. 6 is a schematic cross-sectional view along section line C-C′ in FIG. 5.

FIG. 7 is an enlarged perspective view of a region R2 in FIG. 1.

FIG. 8 is a schematic cross-sectional view along section line D-D′ in FIG. 7.

FIG. 9 is an enlarged perspective view of a region R3 in FIG. 1.

FIG. 10 is a schematic perspective view of partial elements of a piezoelectric actuating apparatus according to an embodiment of the invention.

FIG. 11 is a schematic diagram of a rotatable element in a piezoelectric actuating apparatus reciprocatingly swinging relative to a frame around an axis as a center according to an embodiment of the invention.

FIG. 12 is a graph of rotation angle of a rotatable element relative to driving voltage after a piezoelectric actuating apparatus receives a driving signal according to an embodiment of the invention.

FIG. 13 is a graph of sensing voltage relative to rotation angle of a rotatable element when sensing electrodes in a piezoelectric actuating apparatus output a sensing signal according to an embodiment of the invention.

### DESCRIPTION OF THE EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as “top,” “bottom,” “front,” “back,” etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Accordingly, the drawings and descriptions will be regarded as illustrative in nature and not as restrictive.

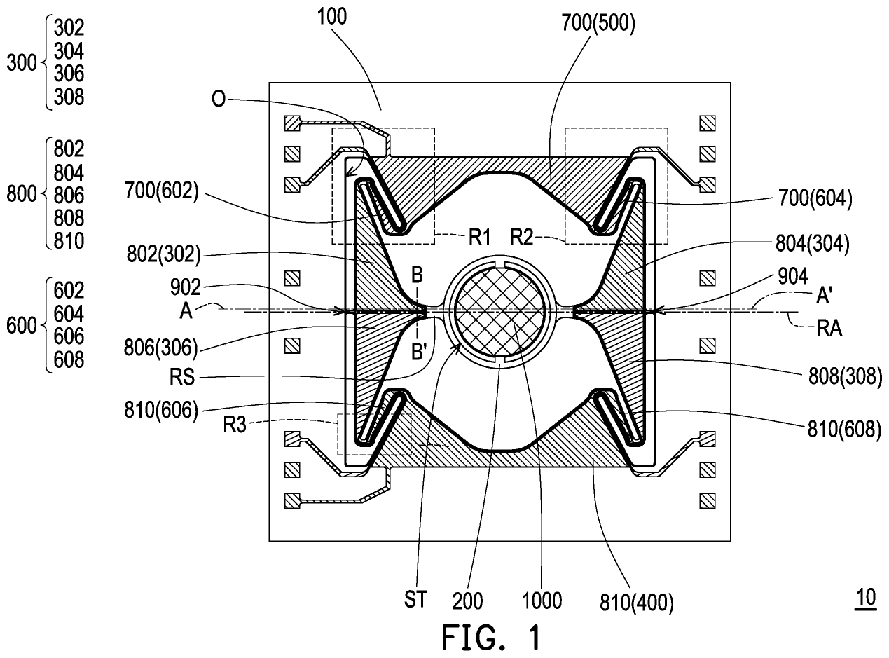

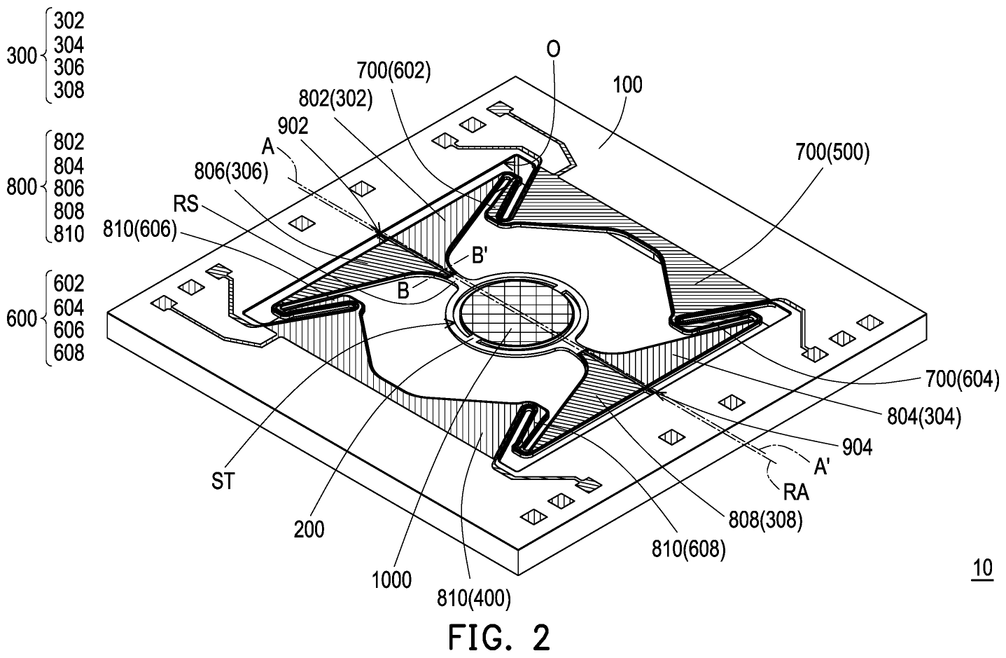

FIG. 1 is a schematic top view of a piezoelectric actuating apparatus according to an embodiment of the invention. FIG. 2 is a schematic perspective view of a piezoelectric actuating apparatus according to an embodiment of the invention. Referring to FIG. 1 and FIG. 2, an embodiment of the invention provides a piezoelectric actuating apparatus 10 including a frame 100, a rotatable element 200, a first actuating element 300, a second actuating element 400, a sensing element 500, a plurality of transmission elements 600, a sensing electrode 700, and a driving electrode 800. The piezoelectric actuating apparatus 10 is, for example, a piezoelectric actuators (transducers).

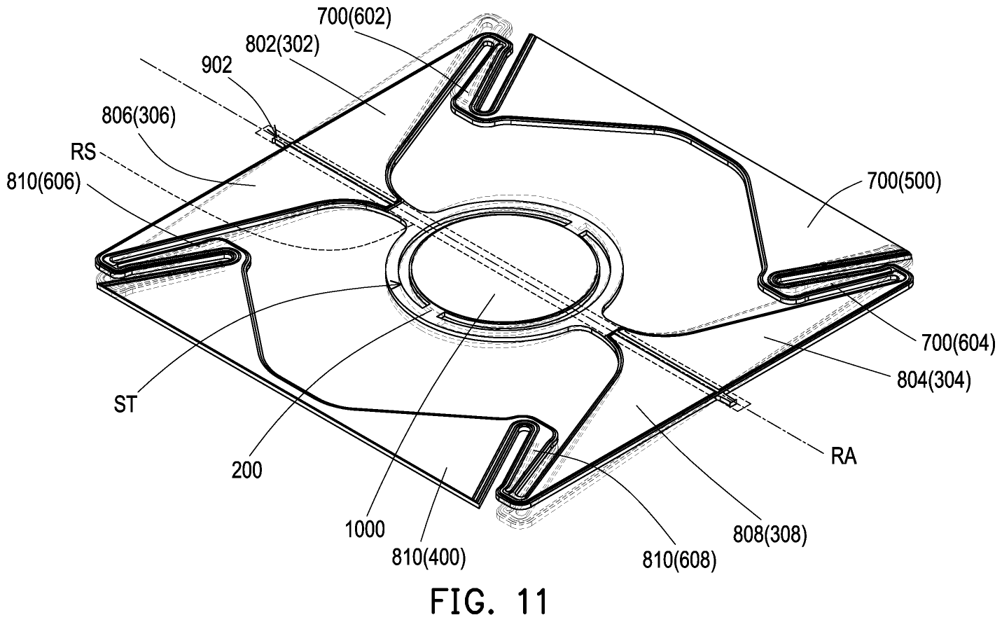

In the embodiment, the frame 100 has an opening O. The rotatable element 200 is located in the opening O and connected to the frame 100 via a rotating shaft structure RS. The rotating shaft structure RS has an axis RA. The rotatable element 200 is configured to reciprocatingly swing relative to the frame 100 around the axis RA as the center (as shown in FIG. 11). The rotatable element 200 is, for example, a micro planar reflector, and an outline of the rotatable element 200 is substantially in a shape of a circular sheet. In other embodiments, the outline of the rotatable element 200 may also be a rectangle or other suitable polygons.

In the embodiment, the first actuating element 300 is disposed between the frame 100 and the rotatable element 200, and the first actuating element 300 is connected to the rotatable element 200. The second actuating element 400 is disposed between the frame 100 and the rotatable element 200, and the second actuating element 400 is connected to the frame 100. The sensing element 500 is disposed between the frame 100 and the rotatable element 200, and the sensing element 500 is connected to the frame 100. The first actuating element 300, the second actuating element 400, and the sensing element 500 surround the rotatable element 200. The second actuating element 400 and the sensing element 500 are extended from a side of the frame 100 into the opening O of the frame 100. In the embodiment, on a reference plane parallel to the rotatable element 200 when not being rotated, the second actuating element 400 and the sensing element 500 are, for example, U-shaped or C-shaped. The contours of the second actuating element 400 and the sensing element 500 are plano-concave shape, the contours of the second actuating element 400 and the sensing element 500 are straight lines at a side toward the frame 100, and concave curve inward at a side toward the rotatable element 200. In the embodiment, the second actuating element 400 and the sensing element 500 are symmetrically disposed at two opposite sides of the axis RA of the rotating shaft structure RS with the axis RA as the center, so that the piezoelectric actuating apparatus 10 is more stable during operation.

In the embodiment, the transmission elements 600 are disposed between the first actuating element 300 and the second actuating element 400 and between the first actuating element 300 and the sensing element 500, and the second actuating element 400 and the sensing element 500 are coupled to the rotatable element 200 via the transmission elements 600. The sensing electrode 700 is disposed on the sensing element 500 and a part of the transmission elements 600. The driving electrode 800 is disposed on the first actuating element 300, the second actuating element 400, and another part of the transmission elements 600.

In an embodiment, the first actuating element 300, the second actuating element 400, the sensing element 500, and the transmission elements 600 include a piezoelectric material. The driving electrode 800 is configured to receive a driving signal to deform the second actuating element 400, the first actuating element 300, and the transmission elements 600 so as to drive the rotatable element 200 to rotate. The driving signal may be generated by a driving circuit. When the first actuating element 300 and the second actuating element 400 are enabled to have a positive voltage, the piezoelectric material generates a compressive strain to drive the first actuating element 300 and the second actuating element 400 to generate contraction deformation and deflect upward relative to the frame 100, and drive the rotatable element 200 to rotate around a direction with the axis RA of the rotating shaft structure RS as the central axis. In contrast, when the first actuating element 300 and the second actuating element 400 are enabled to have a negative voltage, the piezoelectric material generates a tensile strain to drive the first actuating element 300 and the second actuating element 400 to generate tensile deformation and deflect downward relative to the frame 100 and drive the rotatable element 200 to rotate around a direction opposite to the above direction with the axis RA of the rotating shaft structure RS as the central axis.

The sensing electrode 700 is configured to receive a sensing voltage generated by a deformation of the sensing element 500 caused by the rotation of the rotatable element 200, and output a sensing signal. When the driving electrode 800 on the first actuating element 300 and the second actuating element 400 is applied with a positive voltage to drive the rotatable element 200 to rotate, the sensing electrode 700 has a negative voltage since the sensing element 500 is deformed in a direction opposite to that of the first actuating element 300 and the second actuating element 400, thereby generating a corresponding sensing signal. When the driving electrode 800 is applied with the positive voltage and the negative voltage alternately, the rotatable element 200 reciprocates and rotates around the axis RA by a predetermined angle.

In the embodiment, the first actuating element 300 includes a plurality of first sub-actuating elements 302, 304, 306, 308. The first sub-actuating elements 302, 304, 306, 308 are symmetrically disposed adjacent to the rotating shaft structure RS with the axis RA of the rotating shaft structure RS as the center. On a reference plane parallel to the rotatable element 200 when not being rotated, the first sub-actuating elements 302, 304, 306, 308 are triangular.

In the embodiment, the transmission elements 600 are configured to transmit the actuating force from the second actuating element 400 to the first actuating element 300, and the transmission elements 600 also have the function of releasing stress. The transmission elements 600 are flexible bodies (or transmission springs). On a reference plane parallel to the rotatable element 200 when not being rotated, the transmission elements 600 are, for example, S-shaped or curve-shaped, and the bends on the S-shape or curve-shape of the transmission elements 600 may convert part of the stress into structural deformation to release the stress on the bends on the transmission elements 600, thus facilitating the reduction of the risk of damage to the piezoelectric actuating apparatus 10.

In the embodiment, the number of the plurality of transmission elements 600 is embodied as four, including a first transmission element 602, a second transmission element 604, a third transmission element 606, and a fourth transmission element 608. The transmission elements 600 are symmetrically disposed at two opposite sides of the axis RA of the rotating shaft structure RS with the axis RA as the center. Each of the transmission elements 600 is connected between one of the first sub-actuating elements 302, 304, 306, 308 and one of the second actuating element 400 and the sensing element 500. For example, the first transmission element 602 and the second transmission element 604 are respectively connected between the first sub-actuating elements 302 and 304 and the sensing element 500, and after the vibration energy of the rotatable element 200 is first transmitted to the first sub-actuating elements 302 and 304, the first transmission element 602 and the second transmission element 604 are configured to transmit the vibration energy of the rotatable element 200 from the first sub-actuating elements 302 and 304 to the sensing element 500. The third transmission element 606 and the fourth transmission element 608 are respectively connected between the first sub-actuating elements 306 and 308 and the second actuating element 400, and the third transmission element 606 and the fourth transmission element 608 are configured to transmit the actuating force from the second actuating element 400 to the first sub-actuating elements 306 and 308 to drive the rotatable element 200 to rotate.

In the embodiment, the sensing electrode 700 is disposed on the sensing element 500 and extended and disposed on the transmission elements 600 (i.e., the first transmission element 602 and the second transmission element 604) adjacent to the sensing element 500.

In the embodiment, the driving electrode 800 includes five sub-driving electrodes 802, 804, 806, 808, 810. The sub-driving electrodes 802, 804, 806, 808, 810 are respectively disposed on one of the first sub-actuating elements 302, 304, 306, 308 and the second actuating element 400. For example, the sub-driving electrodes 802, 804, 806, 808 are disposed on the first sub-actuating elements 302, 304, 306, 308 respectively, and the sub-driving electrode 810 is disposed on the second actuating element 400. The sub-driving electrode 810 disposed on the second actuating element 400 is extended and disposed on the transmission elements 600 (i.e., the third transmission element 606 and the fourth transmission element 608) adjacent to the second actuating element 400. The sub-driving electrodes 802 and 806 are not connected to each other, and the sub-driving electrodes 804 and 808 are not connected to each other.

In the embodiment, when the driving electrode 800 receives driving signals so that the first actuating element 300 and the second actuating element 400 drive the rotatable element 200 to rotate, among the sub-driving electrodes 802, 804, 806, 808 disposed on the first sub-actuating elements 302, 304, 306, 308, the driving signals received by the sub-driving electrodes located at a same side of the axis RA of the rotating shaft structure RS have a same phase, and the driving signals received by the sub-driving electrodes located at different sides of the axis RA have opposite phases. The driving signal received by the sub-driving electrode 810 disposed on the second actuating element 400 and the driving signals received by the sub-driving electrodes 806 and 808 disposed on the first sub-actuating elements 306 and 308 adjacent to the second actuating element 400 have opposite phases. In other words, the driving signals received by the sub-driving electrodes 802, 804, 810 have a phase, and the driving signals received by the sub-driving electrodes 806 and 808 have a phase. The driving signals received by the sub-driving electrodes 802, 804, 810 and the driving signals received by the sub-driving electrodes 806 and 808 have opposite phases.

In the embodiment, the first actuating element 300 is configured to generate a torque actuating force, and the second actuating element 400 is configured to generate a linear actuating force. After the sub-driving electrodes 802, 804, 806, 808, 810 receive the driving signal(s), the second actuating element 400 is driven, the second actuating element 400 generates a (linear) actuating force perpendicular to a reference plane parallel to the rotatable element 200 when not being rotated, and the first actuating element 300 is used as a moment arm to generate torque to drive the rotatable element 200 to rotate. The first actuating element 300 is not only used as the moment arm of the second actuating element 400, but also the first actuating element 300 itself is driven to generate torque. That is, the first actuating element 300 has the functions of acting as a moment arm and generating torque at the same time, thus achieving the effect of effectively utilizing the area of the element. In the embodiment, the first actuating element 300 itself may generate torque, and the actuating force from the second actuating element 400 may be transmitted via the transmission elements 600 to generate a larger torque. Therefore, the piezoelectric actuating apparatus 10 may achieve a large scanning angle via the integration of the first actuating element 300 and the second actuating element 400.

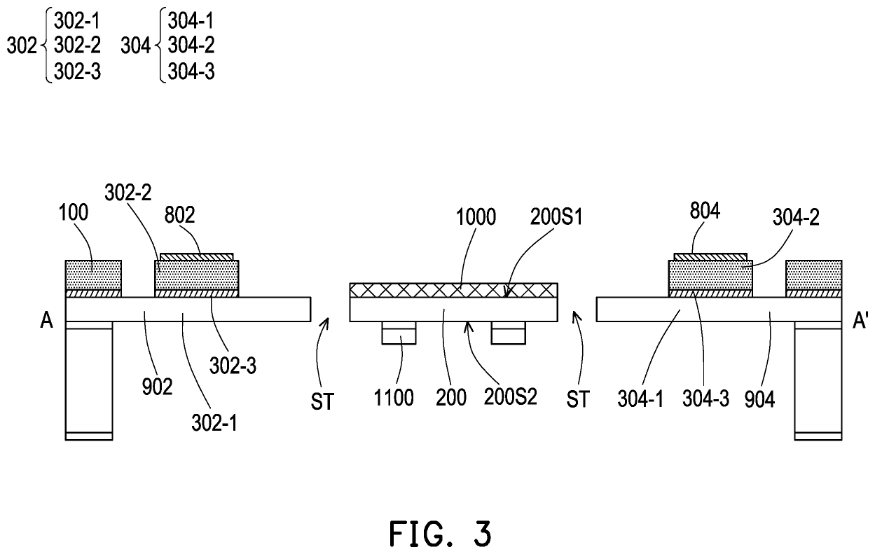

FIG. 3 is a schematic cross-sectional view along section line A-A′ in FIG. 1 or FIG. 2. In FIG. 1 or FIG. 2, section line A-A′ and the axis RA are parallel to each other but are not overlapped. Please refer to FIG. 1, FIG. 2, and FIG. 3, in the embodiment, the first sub-actuating element 302 includes an actuating body 302-1, a piezoelectric material 302-2, and a lower electrode 302-3. The first sub-actuating element 304 includes an actuating body 304-1, a piezoelectric material 304-2, and a lower electrode 304-3.

In the embodiment, the piezoelectric actuating apparatus 10 further includes a reflective layer 1000 disposed on a first surface 200S1 of the rotatable element 200. The reflective layer 1000 is, for example, a metal reflective layer or a mirror. The rotatable element 200 has two slots ST. The two slots ST surround the reflective layer 1000, and the slots ST are, for example, through holes passing through the rotatable element 200 or grooves recessed relative to the surface of the rotatable element 200. The axis RA of the rotating shaft structure RS passes through the two slots ST, whereby the torsional stress generated at the connection between the rotating shaft structure RS and the frame 100 due to the reciprocating rotation of the rotatable element 200 may be released.

In the embodiment, the piezoelectric actuating apparatus 10 further includes elastic elements 902 and 904. The elastic elements 902 and 904 are disposed between the frame 100 and the first actuating element 300 along the axis RA of the rotating shaft structure RS. The elastic elements 902 and 904 are respectively located at two opposite sides of the rotatable element 200, the first sub-actuating elements 302 and 306 are connected to the frame 100 via the elastic element 902, and the first sub-actuating elements 304 and 308 are connected to the frame 100 via the elastic element 904. The elastic elements 902 and 904 are, for example, springs, and are configured to limit the amount of deformation of at least one of the first actuating element 300, the second actuating element 400, the sensing element 500, and the transmission elements 600, in order to prevent the piezoelectric actuating apparatus 10 from being damaged due to excessive deformation or actuating force.

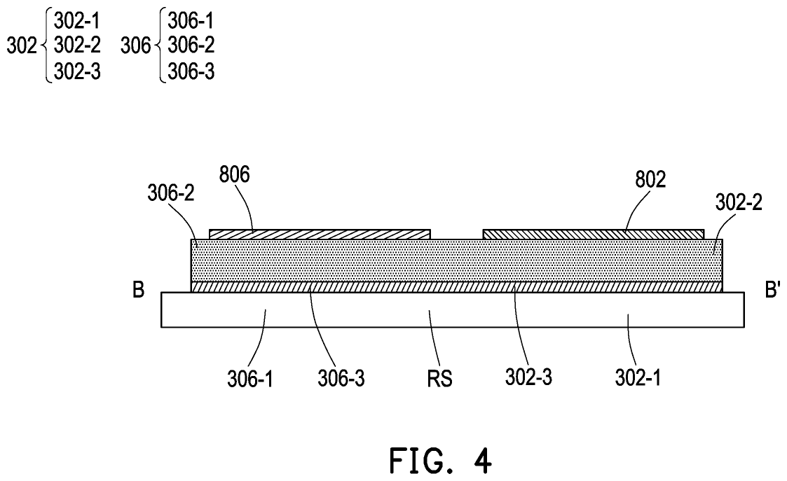

FIG. 4 is a schematic cross-sectional view along section line B-B′ in FIG. 1 or FIG. 2. Please refer to FIG. 1, FIG. 2, and FIG. 4, in the embodiment, the first sub-actuating element 306 includes an actuating body 306-1, a piezoelectric material 306-2, and a lower electrode 306-3. The actuating body 306-1 and the actuating body 302-1 are connected to each other, the piezoelectric material 306-2 and the piezoelectric material 302-2 are connected to each other, and the lower electrode 306-3 and the lower electrode 302-3 are connected to each other.

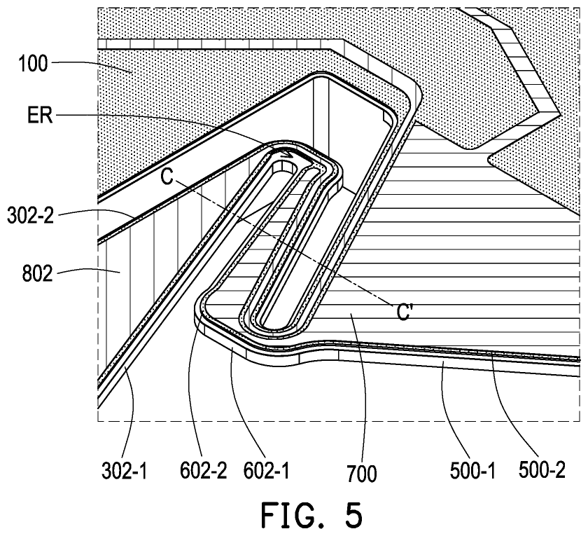

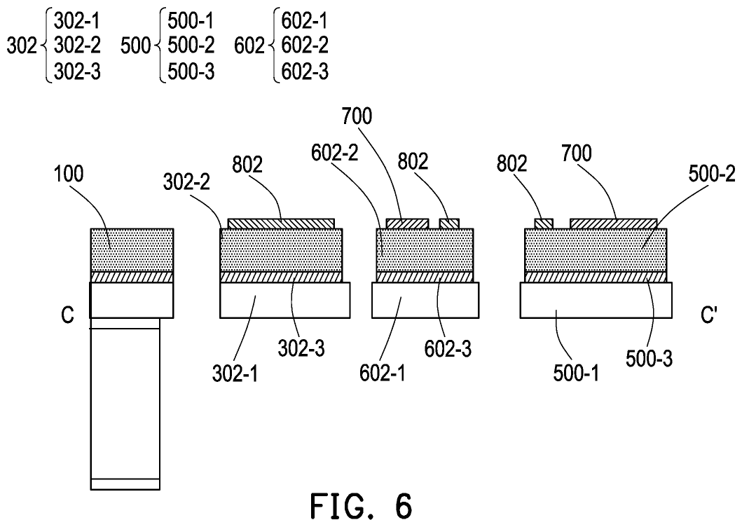

FIG. 5 is an enlarged perspective view of a region R1 in FIG. 1. FIG. 6 is a schematic cross-sectional view along section line C-C′ in FIG. 5. Please refer to FIG. 5 and FIG. 6, in the embodiment, the sensing element 500 includes a sensing body 500-1, a piezoelectric material 500-2, and a lower electrode 500-3. The transmission elements 600 include a transmission body, a piezoelectric material, and a lower electrode. For example, the first transmission element 602 includes a transmission body 602-1, a piezoelectric material 602-2, and a lower electrode 602-3, wherein the lower electrode 602-3 is disposed between the transmission body 602-1 and the piezoelectric material 602-2. The driving electrode 800 and the sensing electrode 700 may be disposed on the piezoelectric material of the transmission elements 600. For example, as shown in FIG. 5 and FIG. 6, the sub-driving electrode 802 and the sensing electrode 700 are disposed on the piezoelectric material 602-2 of the first transmission element 602. The sub-driving electrode 802 disposed on the first sub-actuating element 302 and the sensing electrode 700 disposed on the sensing element 500 are extended and disposed on the first transmission element 602. Along a direction parallel to the axis RA, the sub-driving electrode 802 and the sensing electrode 700 are alternately disposed.

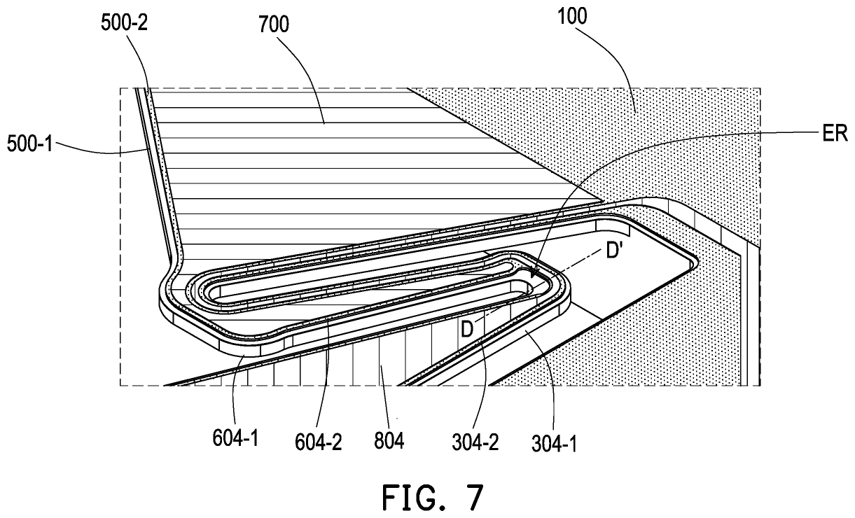

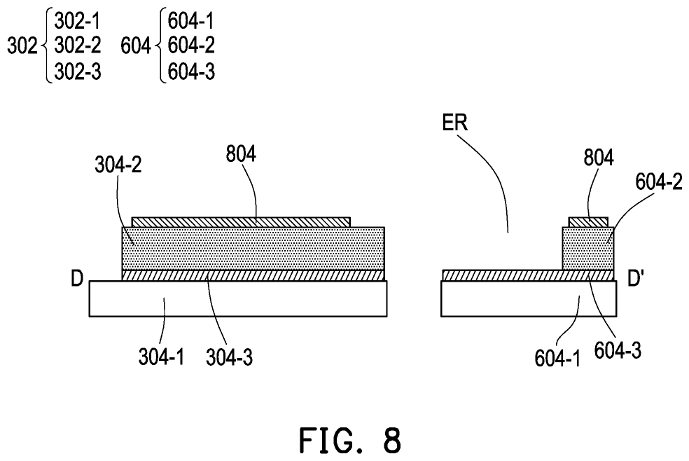

FIG. 7 is an enlarged perspective view of a region R2 in FIG. 1. FIG. 8 is a schematic cross-sectional view along section line D-D′ in FIG. 7. Please refer to FIG. 7 and FIG. 8, in the embodiment, the second transmission element 604 includes a transmission body 604-1, a piezoelectric material 604-2, and a lower electrode 604-3. A blank area ER is provided at the connection between the transmission elements 600 and the first actuating element 300, and the blank area ER is an area where the driving electrode 800 and the piezoelectric material are not provided. For example, in FIG. 5, there is the blank area ER at the connection between the first transmission element 602 and the first sub-actuating element 302, and in the blank area ER, only the driving body 602-1 and the lower electrode 602-3 are disposed, and the piezoelectric material 602-2, the sub-driving electrode 802, and the sensing electrode 700 are not disposed. In FIG. 7 or FIG. 8, the blank area ER is provided at the connection between the second transmission element 604 and the first sub-actuating element 304. In the blank area ER, only the transmission body 604-1 and the lower electrode 604-3 are disposed, and the piezoelectric material 604-2, the sub-driving electrode 804, and the sensing electrode 700 are not disposed. Since the connection between the transmission elements 600 and the first actuating element 300 is the point of maximum stress on the mechanism, and the piezoelectric material is a brittle material that may not withstand too much stress, the blank area ER is provided at the connection between the transmission elements 600 and the first actuating element 300 to facilitate the reduction of the risk of damage to the piezoelectric actuating apparatus 10.

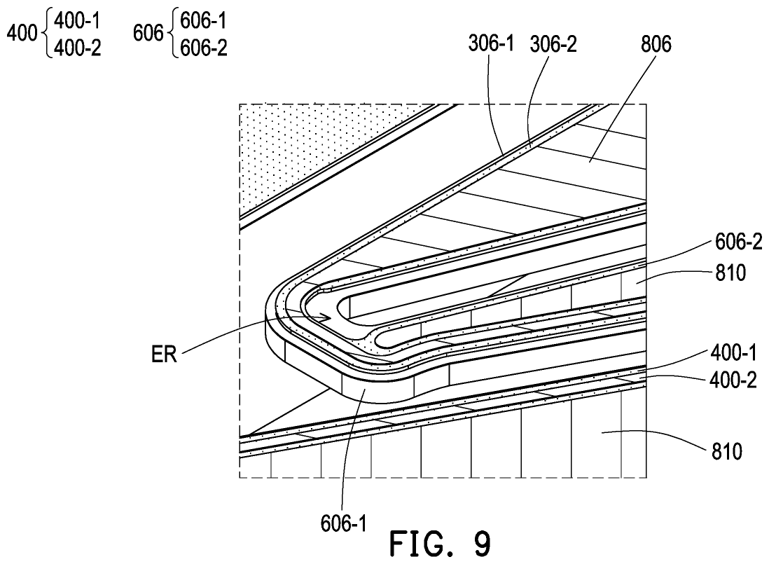

FIG. 9 is an enlarged perspective view of a region R3 in FIG. 1. Referring to FIG. 9, in the embodiment, the second actuating element 400 includes an actuating body 400-1, a piezoelectric material 400-2, and a lower electrode (not shown), wherein the lower electrode is disposed between the actuating body 400-1 and the piezoelectric material 400-2. The third transmission element 606 includes a transmission body 606-1, a piezoelectric material 606-2, and a lower electrode (not shown), wherein the lower electrode is disposed between the transmission body 606-1 and the piezoelectric material 606-2. Two sub-driving electrodes may be disposed on the piezoelectric material of the transmission elements 600. For example, as shown in FIG. 9, the sub-driving electrode 806 and the sub-driving electrode 810 are disposed on the piezoelectric material 606-2 of the third transmission element 606. The sub-driving electrode 806 disposed on the first sub-actuating element 306 and the sub-driving electrode 810 disposed on the second actuating element 400 are extended and disposed on the third transmission element 606. Along a direction parallel to the axis RA, the sub-driving electrode 806 and the sub-driving electrode 810 are alternately disposed. The blank area ER is provided at the connection between the third transmission element 606 and the first sub-actuating element 306.

The first sub-actuating element 308 also includes (not shown) an actuating body, a piezoelectric material, and a lower electrode, and the lower electrode is disposed between the actuating body and the piezoelectric material. The fourth transmission element 608 also includes (not shown) a transmission body, a piezoelectric material, and a lower electrode, and the lower electrode is disposed between the transmission body and the piezoelectric material. In an embodiment, the actuating bodies 302-1, 304-1, 306-1, 400-1, the sensing body 500-1, the transmission bodies 602-1, 604-1, 606-1 and the actuating body corresponding to the first sub-actuating element 308 and the transmission body of the second transmission element 608 are connected to each other and may be integrally formed. The piezoelectric materials 302-2, 304-2, 306-2, 400-2, 500-2, 602-2, 604-2, 606-2 and the piezoelectric materials corresponding to the first sub-actuating element 308 and the second transmission element 608 are connected to each other and may be integrally formed. The lower electrodes 302-3, 304-3, 306-3, 500-3, 602-3, 604-3 and the lower electrodes corresponding to the first sub-actuating element 308, the second actuating element 400, the third transmission element 606, and the fourth transmission element 608 are connected to each other and may be integrally formed.

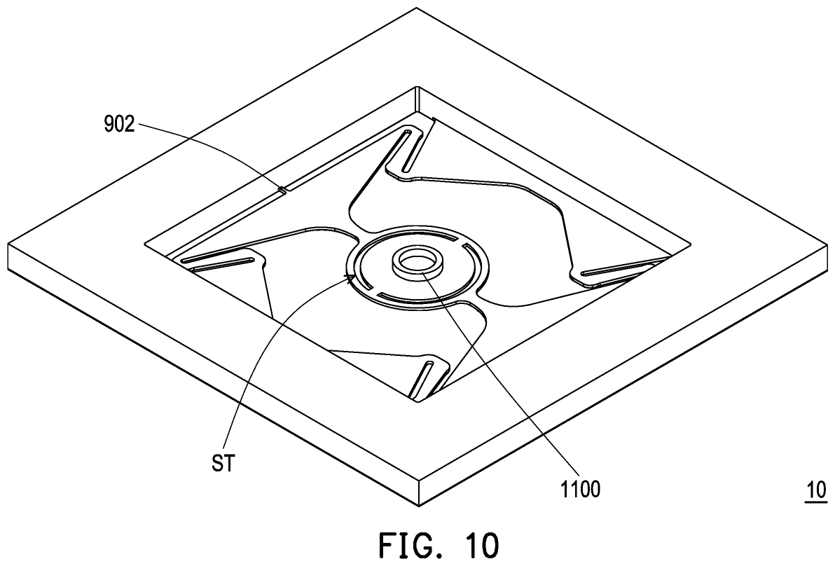

FIG. 10 is a schematic perspective view of partial elements of a piezoelectric actuating apparatus according to an embodiment of the invention. FIG. 10 omits the reflective layer 1000, the sensing electrode 700, the driving electrode 800, the piezoelectric material and the lower electrode of the first actuating element 300, the piezoelectric material and the lower electrode of the second actuating element 400, and the piezoelectric material and the lower electrode of the sensing element in FIG. 3. Please refer to FIG. 3 and FIG. 10, in the embodiment, the piezoelectric actuating apparatus 10 further includes a reinforcing structure 1100 disposed on a second surface 200S2 of the rotatable element 200 opposite to the first surface 200S1. The reinforcing structure 1100 is ring-shaped. The configuration of the reinforcing structure 1100 may enhance the rigidity of the rotatable element 200. The reinforcing structure 1100 is, for example, an annular structure surrounding an edge of the rotatable element 200, or inner and outer annular structures surrounding the edge and a central region of the rotatable element 200, and at least one connecting rib is configured to be connected between the two annular structures.

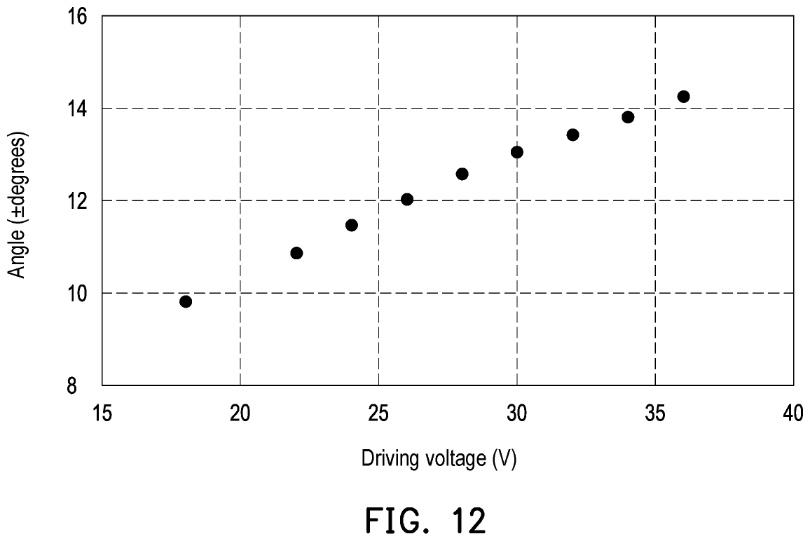

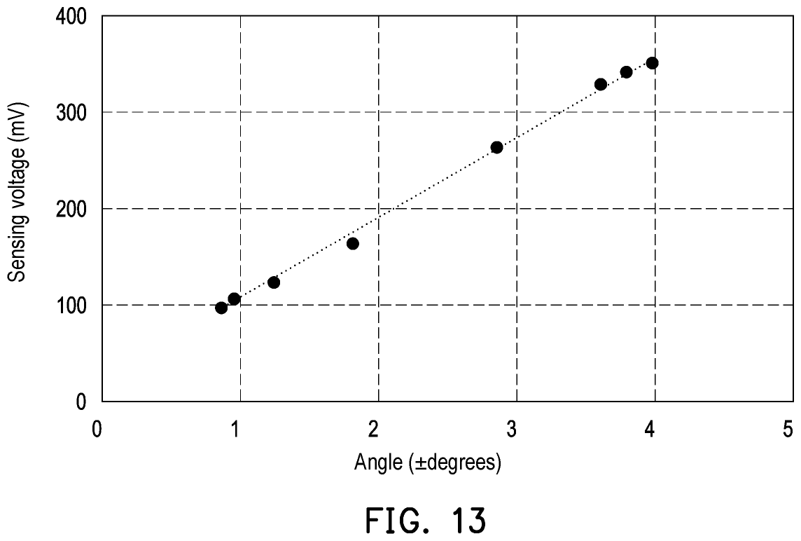

FIG. 11 is a schematic diagram of a rotatable element in a piezoelectric actuating apparatus reciprocatingly swinging relative to a frame around an axis as a center according to an embodiment of the invention. FIG. 12 is a graph of rotation angle of a rotatable element relative to driving voltage after a piezoelectric actuating apparatus receives a driving signal according to an embodiment of the invention. FIG. 13 is a graph of sensing voltage relative to rotation angle of a rotatable element when a sensing electrode in a piezoelectric actuating apparatus outputs a sensing signal according to an embodiment of the invention. In FIG. 11 and FIG. 12, there is a good linear relationship between voltage and angle. Therefore, the rotation angle of the rotatable element 200 in the piezoelectric actuating apparatus 10 of an embodiment of the invention may be well controlled. In FIG. 13, the slope of sensing voltage relative to angle may reach 83 mV/degree. Therefore, the piezoelectric actuating apparatus 10 not only makes the sensing signal more realistically present the degree of rotation of the rotatable element 200, but may also effectively improve the sensing capability of the piezoelectric actuating apparatus 10, and the piezoelectric actuating apparatus 10 has a large scanning angle and a high scanning frequency. The piezoelectric actuating apparatus 10 of the embodiment may be applied to projection imaging, for example, and the scanning angle of the piezoelectric actuating apparatus 10 is the visible range of the image, that is, the size of the image. The scanning frequency determines the fill rate of the scanning track to the image. The higher the scanning frequency, the higher the fill rate, that is, images with higher resolution may be presented.

Based on the above, in an embodiment of the invention, the piezoelectric actuating apparatus includes the rotatable element, the first actuating element, the second actuating element, the transmission elements, and the sensing element. The second actuating element and the sensing element are coupled to the rotatable element via the transmission elements. The first actuating element, the second actuating element, the transmission elements, and the sensing element are symmetrically disposed in the frame with the rotatable element as the center, thus facilitating the miniaturization of the piezoelectric actuating apparatus. Therefore, the piezoelectric actuating apparatus may achieve the effects of high control accuracy, large scanning angle, and high scanning frequency under the design of small element size. Moreover, since the piezoelectric material is used as the material of the actuating elements, the piezoelectric actuating apparatus may also meet the requirement of easy mass production.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A piezoelectric actuating apparatus, comprising:
a frame, having an opening;
a rotatable element, located in the opening and connected to the frame via a rotating shaft structure, the rotating shaft structure has an axis, and the rotatable element is configured to reciprocatingly swing relative to the frame around the axis as a center;
a first actuating element, disposed between the frame and the rotatable element, and the first actuating element is connected to the rotatable element;
a second actuating element, disposed between the frame and the rotatable element, and the second actuating element is connected to the frame;
a sensing element, disposed between the frame and the rotatable element, the sensing element is connected to the frame, and the sensing element and the second actuating element are symmetrically disposed at two opposite sides of the axis of the rotating shaft structure with the axis as the center;
a plurality of transmission elements, disposed between the first actuating element and the second actuating element and between the first actuating element and the sensing element, and the second actuating element and the sensing element are coupled to the rotatable element via the transmission elements;
a sensing electrode, disposed on a part of the transmission elements and the sensing element; and
a driving electrode, disposed on another part of the transmission elements, the first actuating element, and the sensing element.

2. The piezoelectric actuating apparatus of claim 1, wherein the first actuating element, the second actuating element, the sensing element, and the transmission elements comprise a piezoelectric material.

3. The piezoelectric actuating apparatus of claim 1,
wherein the driving electrode is configured to receive a driving signal to deform the second actuating element, the first actuating element, and the transmission elements so as to drive the rotatable element to rotate;
wherein the sensing electrode is configured to receive a sensing voltage generated by a deformation of the sensing element caused by a rotation of the rotatable element, and output a sensing signal.

4. The piezoelectric actuating apparatus of claim 1, wherein the first actuating element comprises a plurality of first sub-actuating elements, and the first sub-actuating elements are symmetrically disposed adjacent to the rotating shaft structure with the axis of the rotating shaft structure as the center.

5. The piezoelectric actuating apparatus of claim 4, wherein the first sub-actuating elements are triangular.

6. The piezoelectric actuating apparatus of claim 1, wherein the second actuating element is U-shaped or C-shaped.

7. The piezoelectric actuating apparatus of claim 1, wherein the transmission elements are symmetrically disposed at the two opposite sides of the axis of the rotating shaft structure with the axis as the center.

8. The piezoelectric actuating apparatus of claim 1, wherein the first actuating element comprises a plurality of first sub-actuating elements, the transmission elements are respectively S-shaped or curve-shaped, and each of the transmission elements is connected between one of the first sub-actuating elements and one of the second actuating element and the sensing element.

9. The piezoelectric actuating apparatus of claim 1, wherein the first actuating element comprises a plurality of first sub-actuating elements, the driving electrode comprises five sub-driving electrodes, and the five sub-driving electrodes are respectively disposed on one of the first sub-actuating elements and the second actuating element, wherein the sub-driving electrode disposed on the second actuating element is extended and disposed on the transmission elements adjacent to the second actuating element.

10. The piezoelectric actuating apparatus of claim 9, wherein when the driving electrode receives driving signals so that the first actuating element and the second actuating element drive the rotatable element to rotate, among the sub-driving electrodes disposed on the first sub-actuating elements, the driving signals received by the sub-driving electrodes located at a same side of the axis of the rotating shaft structure have a same phase, and the driving signals received by the sub-driving electrodes located at different sides of the axis have opposite phases.

11. The piezoelectric actuating apparatus of claim 10, wherein the driving signal received by the sub-driving electrode disposed on the second actuating element and the driving signals received by the sub-driving electrodes disposed on the first sub-actuating elements adjacent to the second actuating element have opposite phases.

12. The piezoelectric actuating apparatus of claim 1, further comprising:
an elastic element, disposed between the frame and the first actuating element along the axis of the rotating shaft structure.

13. The piezoelectric actuating apparatus of claim 1, wherein the rotatable element has two slots, and the axis of the rotating shaft structure passes through the two slots.

14. The piezoelectric actuating apparatus of claim 1, wherein a blank area is provided at a connection between the transmission elements and the first actuating element, and the blank area is an area where no piezoelectric material is disposed.

15. The piezoelectric actuating apparatus of claim 1, further comprising a reflective layer disposed on a first surface of the rotatable element.

16. The piezoelectric actuating apparatus of claim 15, further comprising:
a reinforcing structure, disposed on a second surface of the rotatable element opposite to the first surface.

17. The piezoelectric actuating apparatus of claim 16, wherein the reinforcing structure is ring-shaped.
